(19) United States
(12) Patent Application Publication
(10) Pub. No.: US 2003/0052807 A1
(43) Pub. Date: Mar. 20, 2003

(54) Noise cancellation apparatus and method

(76) Inventors: Tsuei-Chi Yeh, Hsinchu City (TW); Ping-Ying Chu, Tainan Hsien (TW); Liang-Hao Hsu, Hsinchu (TW)

Correspondence Address: Raymond Sun, 12420 Woodhall Way, Tustin, CA, 92782, US

(21) Appl. No.: 09/952,734

(22) Filed: Sep. 14, 2001

(51) Int. Cl. H03M 1/66

(52) U.S. Cl. 341/144

(57) ABSTRACT

An apparatus for canceling noise in a PC environment includes a receiver positioned inside the computer case that inputs noise inside the computer case, a processor coupled to the receiver and having a waveform generation device that generates a cancellation waveform that is inverse to the waveform of the input noise, and a speaker coupled to the processor for broadcasting the cancellation waveform. A method for canceling noise in a PC environment includes inputting a noise, determining a cyclical waveform that is representative of the noise, generating a cancellation waveform that is the reverse of the cyclical waveform, and mixing the sound from the cancellation waveform with the noise.

### BACKGROUND OF THE INVENTION

1. Field of the Invention

The present invention relates generally to personal computers, and in particular, to an apparatus and method for canceling active noise generated within the computer case and surrounding environment.

2. Background Art

Personal computers (PCs) have proliferated to the point where they have become a necessary appliance in almost every home and business. The core of each PC is its central processing unit (CPU), which is responsible for controlling the operations of the entire PC. Given the large amount of processing work that the CPU must perform, the currently-available CPUs consume large amounts of power, which in turn generates a large amount of heat inside the computer case of the PC. To address this problem, virtually every PC is provided with a fan that is positioned inside the computer case, with the fan functioning to dissipate the heat that is being generated. Unfortunately, fans suffer from the drawback that they are very noisy.

Thus, there still remains a need for an apparatus and method that overcomes the noise generated by fans housed inside the computer case of conventional PCs.

### SUMMARY OF THE INVENTION

It is an object of the present invention to provide an apparatus and method for canceling the noise generated inside the computer case of a conventional PC.

It is another object of the present invention to cancel the noise generated inside the computer case of a conventional PC using as many of the original components that are found in a conventional PC as possible.

It is yet another object of the present invention to cancel the noise generated inside the computer case of a conventional PC in a low-cost manner by minimizing the introduction of additional hardware components.

To accomplish the objectives of the present invention, there is provided an apparatus and method of canceling noise in a PC environment. The apparatus includes a receiver positioned inside the computer case that inputs noise inside the computer case, a processor coupled to the receiver and having a waveform generation device that generates a cancellation waveform that is inverse to the waveform of the input noise, and a speaker coupled to the processor for broadcasting the cancellation waveform.

The method of the present invention includes inputting a noise, determining a cyclical waveform that is representative of the noise, generating a cancellation waveform that is the reverse of the cyclical waveform, and mixing the sound from the cancellation waveform with the noise. The cancellation waveform functions to cancel or offset the noise.

### BRIEF DESCRIPTION OF THE DRAWINGS

The invention can be more fully understood by reading the subsequent detailed description of the preferred embodiments, with reference made to the accompanying drawings.

FIG. 1 is a very general schematic block diagram of a noise cancellation apparatus according to one embodiment of the present invention.

FIG. 2 is a schematic block diagram illustrating the components of the apparatus of FIG. 1.

FIG. 3 is a flowchart illustrating the method of operation of the apparatus of FIG. 1.

FIG. 4 is a schematic block diagram of a noise cancellation apparatus according to another embodiment of the present invention.

FIG. 5 is a flowchart illustrating the method of operation of the apparatus of FIG. 4.

FIG. 6A illustrates a noise waveform.

FIG. 6B illustrates a cancellation waveform generated by the present invention.

FIG. 6C illustrates how the cancellation waveform generated by the present invention cancels the noise waveform.

### DETAILED DESCRIPTION OF THE INVENTION

In the following description, for purposes of explanation and not limitation, specific details are set forth in order to provide a thorough understanding of the present invention. However, it will be apparent to one skilled in the art that the present invention may be practiced in other embodiments that depart from these specific details. In certain instances, detailed descriptions of well-known or conventional data processing techniques, hardware devices and circuits are omitted so as to not obscure the description of the present invention with unnecessary detail.

The present invention utilizes the PC's own sound devices (e.g., the PC's sound card or AC97 Codec) and CPU to create a reverse noise (referred to below as a noise cancellation waveform) to cancel or offset the noise in the PC environment. The noise in the PC environment can originate from the fan, or from any other source in the computer case of the PC, or from its immediate vicinity. Although the present invention is being described in connection with a PC, the principles herein are also applicable to any sound device, including but not limited to notebook computers and set-up boxes, among others.

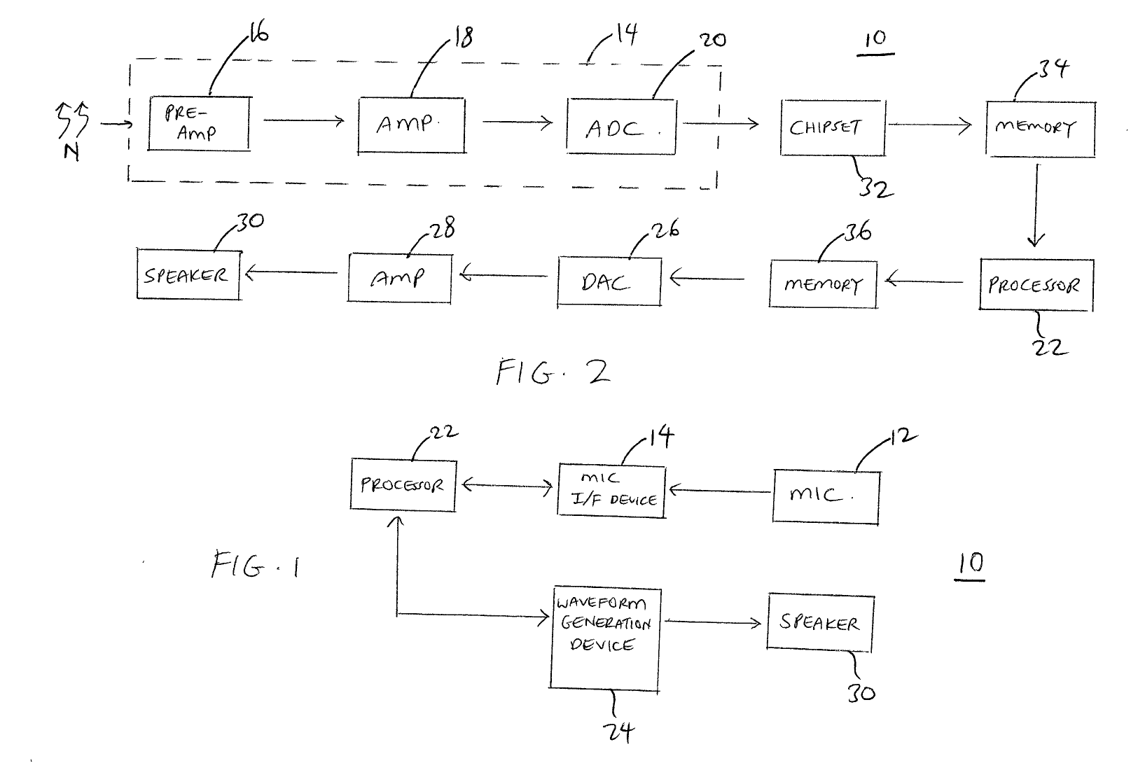

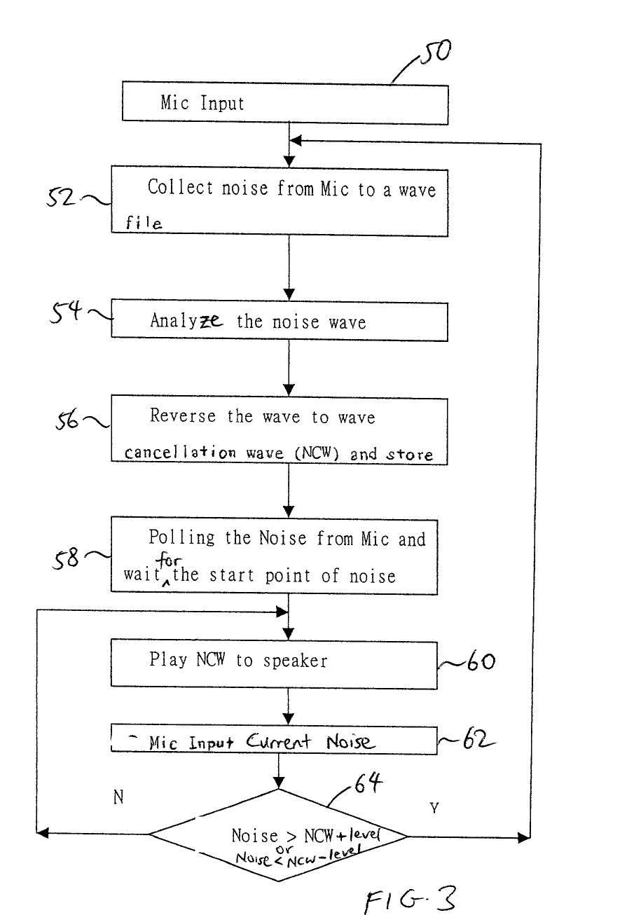

A first non-limiting embodiment of the present invention is illustrated in FIGS. 1-3. FIG. 1 provides a high level schematic that illustrates the principal hardware and software components of a noise cancellation apparatus 10 that operates to cancel or offset the noise in the PC environment. FIG. 2 is a schematic block diagram illustrating the hardware components of the noise cancellation apparatus 10.

The noise cancellation apparatus 10 includes a microphone 12 that can be positioned anywhere inside the computer case (e.g., on the motherboard), and preferably at a location where it is best adapted to pick up a majority of the noise generated by the PC environment. The microphone 12 receives the noise input N, and provides the input to a microphone interface (I/F) device 14. The microphone I/F device 14 can be an AC97 Codec, which is a standard interface chip that is well-known in the industry. Alternatively, the microphone I/F device 14 can be a standard sound chip that is found in most conventional PCs. Both the AC97 Codec and the standard sound chip will include a pre-amplifier 16, an amplifier 18, and an analog-to-digital converter (ADC) 20, as described in greater detail below. The microphone I/F device 14 processes the noise input N from the microphone 12, and then provides the processed noise input N to a processor 22, which can be the PC's CPU. The processor 22 includes a waveform generation device 24 that can be a software module, or firmware. The processor 22 and its waveform generation device 24 execute the method illustrated in FIG. 3 below to generate a noise cancellation waveform (NCW). The NCW is then converted into an analog signal by a digital-to-analog converter (DAC) 26, and amplified by an amplifier 28, before being provided to a speaker set 30 to be emitted or broadcast.

As shown in FIG. 2, the microphone I/F device 14 includes a pre-amplifier 16, an amplifier 18, and an ADC 20. The analog noise input N from the microphone 12 is amplified by the amplifier 18, and then converted into a digital signal by the ADC 20. A chipset 32 is coupled to the ADC 20 to receive the digital noise signal. The chipset 32 can be a standard IC (e.g., the Intel 810) that is provided in the PC, and normally performs a number of functions, including functioning as PCI, USB hub, memory, etc. As used for the present invention, the chipset 32 functions to interface the processor 22 with the microphone I/F device 14. A first memory 34 (which can be a RAM or hard-disk) can be coupled to both the chipset 32 and the processor 22, and functions to store the digital noise signal received from the ADC 20. A second memory 36 can be coupled to both the processor 22 and the DAC 26, and functions to store the NCW generated by the waveform generation device 24.

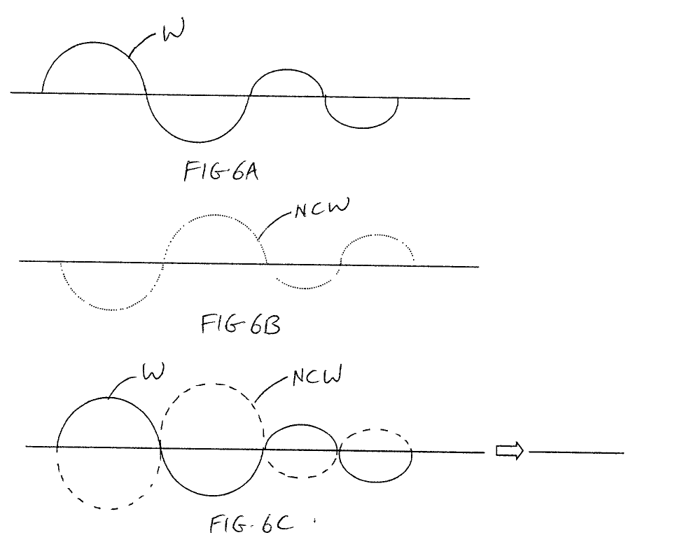

The principles of the noise cancellation method of the present invention will now be briefly described. It has been observed that the noise generated inside a PC (including the noise from the motor of the fan) is generally a constant sound having a waveform that repeats itself in cycles. Therefore, the present invention seeks to locate this cyclical waveform for the input noise N, and then generates and emits a series of reverse waveforms (i.e., the NCW) to cancel or offset the input noise N. FIGS. 6A-6C illustrate these principles in an ideal situation. FIG. 6A illustrates a possible waveform pattern W for an input noise. This waveform pattern W is expected to be cyclical. FIG. 6B illustrates an NCW that is generated to cancel the input noise, which is shown to be the exact inverse or reverse of the wave pattern W. This NCW can also be cyclical. FIG. 6C illustrates the mixing of the waveform pattern W and the NCW, which results in zero (i.e., no) sound in an ideal situation.

FIG. 3 describes the operation of the noise cancellation apparatus 10. In a first step 50, the microphone 12 reads in an input noise N. In step 52, the input noise N is processed by the microphone I/F device 14 in the manner described above, and written to a wave file that is stored in the memory 34. In step 54, the processor 22 analyzes the data for the digital input noise to locate a cyclical waveform that represents the digital input noise. Part of this analysis would include locating a start point and an end point for the appropriate cyclical waveform. Next, in step 56, the processor 22 reverses the cyclical waveform that represents the digital input noise, by taking the inverse of the data for that waveform. The reversed wave is the noise cancellation wave NCW, which is then stored in the memory 36. In step 58, the processor 22 continues to poll the microphone 12 for incoming noise, and attempts to locate the start point of the noise by locating the beginning or starting point of the next waveform. Then, in step 60, the NCW is provided to the speaker 30 via the DAC 26 and the amplifier 28, to be emitted or broadcast at the speaker 30. This NCW will then mix with the noise to cancel or offset the input noise N, as illustrated in FIGS. 6A-6C.

Next, in step 62, the environment noise (which should include the original noise input N mixed with the just-emitted NCW) is again detected by the microphone 12 and processed in the manner described above, and the new noise input is compared, in step 64, with the NCW and a tolerance level (“level”). If the new input noise is greater than, or less than, the tolerance level of the NCW, this means that the noise inside the PC has changed from the previously-determined cyclical waveform, and is most likely louder. Here, the level can be a predetermined or predefined tolerance level that should not be exceeded (i.e., greater or less than) before a new NCW needs to be generated. As a result, processing is returned to step 52 to generate a new NCW to cancel the new noise. If the new input noise is not greater than, or not less than, the tolerance level of the NCW, this means that the noise inside the PC has not changed significantly from the previously-determined cyclical waveform. As a result, processing is returned to step 60 to continue to emit the previously-generated NCW. It is noted that steps 62 and 64 can be implemented after predetermined time intervals, such as once every few seconds.

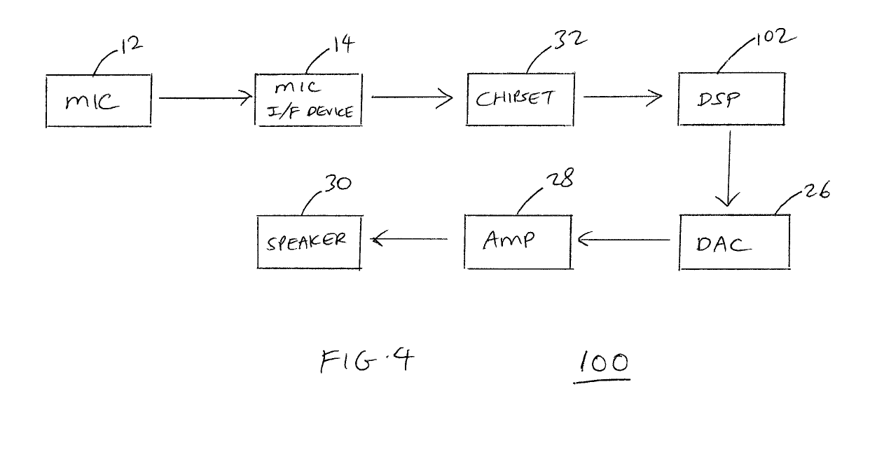

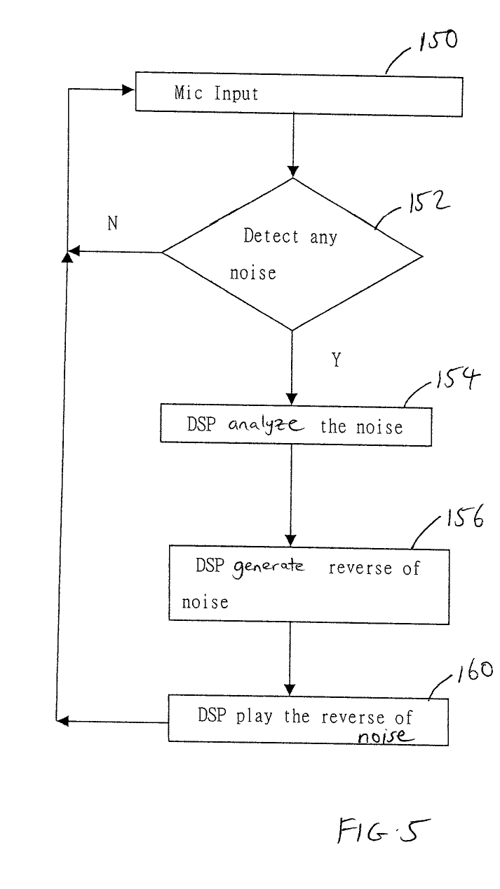

FIGS. 4-5 illustrate a second non-limiting embodiment of the present invention. FIG. 4 is a schematic block diagram illustrating the hardware components of another noise cancellation apparatus 100. As shown in FIG. 4, the microphone 12, the microphone I/F device 14, the chipset 32, the DAC 26, the amplifier 28, and the speaker 30 can be the same as those corresponding components in the apparatus 10 of FIGS. 1-3. However, the apparatus 100 of FIG. 4 differs from the apparatus 10 of FIGS. 1-3 in that the CPU of the PC is not used as the processor. Here, the processor 22 is replaced by a digital signal processor (DSP) unit 102, which includes a digital signal processor. The DSP unit 102 can also be embodied in the form of an ASIC chip. The DSP unit 102 also performs the functions that are performed by the waveform generation device 24. In this regard, the DSP unit 102 can be programmed to itself detect the noise and generate the NCW very quickly. In addition, the high computing power of the DSP unit 102 also means that it is not necessary to save waveform data in a memory, so that the memories 34 and 36 can be omitted. As a result, the apparatus 100 provides for a stand-alone noise cancellation unit to be provided that does not need to be coupled to, nor require the use of, the PC's CPU.

FIG. 5 describes the operation of the noise cancellation apparatus 100. In a first step 150, the microphone 12 reads in an input. In step 152, the DSP unit 102 determines whether the input included any input noise N. If there was no input noise N, processing returns to step 150. If there was input noise N, then in step 154, the DSP unit 102 analyzes the incoming noise, and in step 156, the DSP unit 102 generates the NCW using the principles set forth above. The DSP unit 102 generates the NCW by collecting each point of the noise input N, and then immediately generating a reverse point for an NCW waveform. Then, in step 160, the NCW is provided to the speaker 30 via the DAC 26 and the amplifier 28, to be emitted at the speaker 30. Thus, the NCW is provided on a point-by-point basis to the speaker 30. This NCW should cancel or offset the input noise N, as illustrated in FIGS. 6A-6C. The apparatus 100 operates on a real-time basis (i.e., it continuously generates new NCWs based on the continuously-detected input noise levels), so the loop of steps 62 and 64 in FIG. 3 are omitted from the operation of the apparatus 100.

Thus, the present invention provides an effective method for cancelling undesirable noise in a PC environment, while utilizing the existing components (e.g., the microphone I/F device 14, the chipset 32, the processor or CPU 22) of a conventional PC system to form the basis of its apparatus, thereby lowering the cost of the apparatus.

It will be recognized that the above described invention may be embodied in other specific forms without departing from the spirit or essential characteristics of the disclosure. Thus, it is understood that the invention is not to be limited by the foregoing illustrative details, but rather is to be defined by the appended claims.

What is claimed is:

1. An apparatus, comprising:
a housing;
a receiver positioned inside the housing that inputs noise inside the housing, the input noise having a waveform;
a processor coupled to the receiver, and having a waveform generation device that generates a cancellation waveform that is inverse to the waveform of the input noise; and
a speaker coupled to the processor, the speaker broadcasting the cancellation waveform.

2. The apparatus of claim 1, further including:
an interface coupled between the receiver and the processor for processing the input noise.

3. The apparatus of claim 2, wherein the interface includes an amplifier and an analog-to-digital-converter.

4. The apparatus of claim 1, further including:
a first memory coupled to the interface for storing the input noise.

5. The apparatus of claim 4, further including:
a second memory coupled to the processor for storing the cancellation waveform.

6. The apparatus of claim 1, wherein the processor includes a digital signal processing unit.

7. A method of offsetting a noise, comprising:
inputting a noise;
determining a cyclical waveform that is representative of the noise;
generating a cancellation waveform that is the reverse of the cyclical waveform, the cancellation waveform representative of a sound; and
mixing the sound from the cancellation waveform with the noise to create a mixed result.

8. The method of claim 7, wherein the mixed result has zero sound.

9. The method of claim 7, wherein mixing the sound from the cancellation waveform with the noise includes broadcasting the cancellation waveform in the vicinity of where the noise was inputted.

10. The method of claim 7, further including:
inputting the mixed result which has a waveform;
comparing the cancellation waveform with the waveform for the mixed result; and
determining a second cyclical waveform that is representative of the mixed result;
generating a second cancellation waveform that is the reverse of the second cyclical waveform; and
mixing the sound from the second cancellation waveform with the mixed result.

11. The method of claim 7, further including:
determining the start point of the cyclical waveform.

12. The method of claim 7, further including:
inputting a subsequent noise;
determining a subsequent cyclical waveform that is representative of the subsequent noise; and
generating a second cancellation waveform that is the reverse of the subsequent cyclical waveform if the subsequent cyclical waveform varies from the cancellation waveform by a predetermined tolerance level.

13. An apparatus, comprising:
a housing;
a receiver positioned inside the housing that inputs noise inside the housing, the input noise having a waveform;
a digital signal processing (DSP) unit coupled to the receiver, the DSP unit generating a cancellation waveform that is inverse to the waveform of the input noise; and
a speaker coupled to the DSP unit, the speaker broadcasting the cancellation waveform.

14. The apparatus of claim 13, further including:
an interface coupled between the receiver and the DSP unit for processing the input noise.

15. The apparatus of claim 14, wherein the interface includes an amplifier and an analog-to-digital-converter.
